(19) United States
(12) Patent Application Publication
(10) Pub. No.: US 2024/0222075 A1
(43) Pub. Date: Jul. 4, 2024

(54) PLASMA PROCESSING APPARATUS

(71) Applicant: Tokyo Electron Limited, Tokyo (JP)

(72) Inventors: Naoki MATSUMOTO, Miyagi (JP); Ken KOBAYASHI, Miyagi (JP); Shinya TAMONOKI, Miyagi (JP)

(73) Assignee: Tokyo Electron Limited, Tokyo (JP)

(21) Appl. No.: 18/605,275

(22) Filed: Mar. 14, 2024

Related U.S. Application Data
(63) Continuation of application No. PCT/JP2022/034436, filed on Sep. 14, 2022.

(30) Foreign Application Priority Data
Sep. 15, 2021 (JP) 2021-150606

(51) Int. Cl. H01J 37/32

(52) U.S. Cl. CPC H01J 37/3211; H01J 37/32091; H01J 37/32146; H01J 2237/327; H01J 2237/334

(57) ABSTRACT

A plasma processing apparatus includes a first power source configured to supply a first electric signal to an antenna, the first electric signal including a first RF signal having a first RF frequency; a second power source configured to supply a second electric signal to at least one electrode, the second electric signal including a second RF signal having a second RF frequency; a third power source configured to supply a third electric signal to the at least one electrode, the third electric signal including a third RF signal or a DC signal having a third RF frequency that is lower than the first RF frequency and the second RF frequency; and a controller configured to control the first power source, the second power source, and the third power source so as to selectively execute a first, a second, and a third plasma processing mode.

### CROSS-REFERENCE TO RELATED APPLICATIONS

This application is a bypass continuation application of International Application No. PCT/JP2022/034436 having an international filing date of Sep. 14, 2022 and designating the United States, the international application being based upon and claiming the benefit of priority from Japanese Patent Application No. 2021-150606, filed on Sep. 15, 2021, the entire contents of each are incorporated herein by reference.

### TECHNICAL FIELD

The present disclosure relates to a plasma processing apparatus.

### BACKGROUND

For example, Patent Document 1 proposes a plasma process using an inductively-coupled plasma processing apparatus. For example, in a stacked film in which two or more films such as an organic film, an amorphous carbon film, a silicon oxide film, and a polysilicon film are stacked, a soft and thin film, a hard and thick film, and the like are mixed, and therefore, it is not possible to collectively process all the films in the stacked film at once using the inductively-coupled plasma processing apparatus, and plasma processing apparatuses may be used depending on characteristics of each film.

### CITATION LIST

### Patent Documents

Patent Document 1: JP2019-067503A

### SUMMARY

The present disclosure provides a technology capable of performing etching according to film types in one plasma processing apparatus.

According to an aspect of the present disclosure, there is provided a plasma processing apparatus including: a plasma processing chamber; a substrate support disposed in the plasma processing chamber and including at least one electrode; an antenna disposed above the plasma processing chamber; a first power source configured to supply a first electric signal to the antenna, the first electric signal including a first RF signal having a first RF frequency; a second power source configured to supply a second electric signal to the at least one electrode, the second electric signal including a second RF signal having a second RF frequency; a third power source configured to supply a third electric signal to the at least one electrode, the third electric signal including a third RF signal or DC signal having a third RF frequency that is lower than the first RF frequency and the second RF frequency; and a controller configured to control the first power source, the second power source, and the third power source so as to selectively execute a first plasma processing mode, a second plasma processing mode, and a third plasma processing mode, in which in the first plasma processing mode, the third electric signal is not supplied to the at least one electrode, the first electric signal is supplied to the antenna, and the second electric signal is supplied to the at least one electrode, in the second plasma processing mode, the second electric signal is not supplied to the at least one electrode, the first electric signal is supplied to the antenna, and the third electric signal is supplied to the at least one electrode, and in the third plasma processing mode, the first electric signal is not supplied to the antenna, and the second electric signal and the third electric signal are supplied to the at least one electrode.

According to one aspect, it is possible to perform etching according to film types in one plasma processing apparatus.

### BRIEF DESCRIPTION OF DRAWINGS

FIG. 1 is a view illustrating an example of a plasma processing system according to an embodiment.

FIG. 2 is a schematic cross-sectional view illustrating an example of the plasma processing apparatus according to the embodiment.

FIG. 3 is a view illustrating an example of a matching circuit of two bias pulsed signals according to the embodiment.

FIG. 4 is a flowchart illustrating an example of an etching method according to the embodiment.

FIG. 5 is a view illustrating an example of a stacked film according to the embodiment.

FIG. 6 is a view illustrating an example of application of a pulsed signal in each mode according to the embodiment.

FIG. 7 is a view schematically illustrating states of ion flux, ion energy, and radical flux in each mode according to the embodiment.

FIG. 8 is a schematic cross-sectional view illustrating another example of the plasma processing apparatus according to the embodiment.

FIG. 9 is a view illustrating an example of each signal in each mode according to the embodiment.

FIG. 10 is a view illustrating an example of each signal in each mode according to the embodiment.

FIG. 11 is a view illustrating an example of each signal in each mode according to the embodiment.

### DETAILED DESCRIPTION

Hereinafter, embodiments for implementing the present disclosure will be described with reference to the drawings. In the respective drawings, the same components will be denoted by the same reference numerals, and overlapping descriptions thereof may be appropriately omitted.

### [Plasma Processing System]

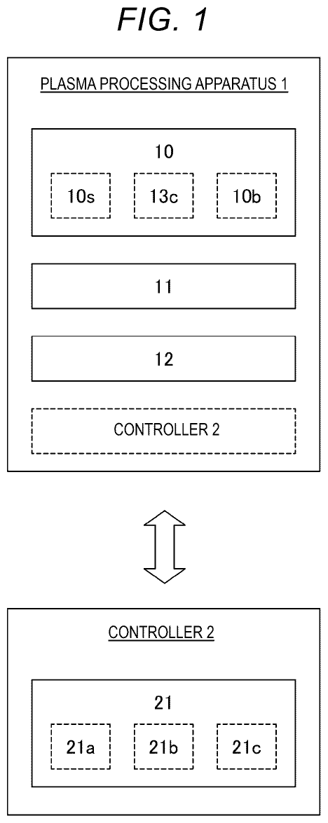

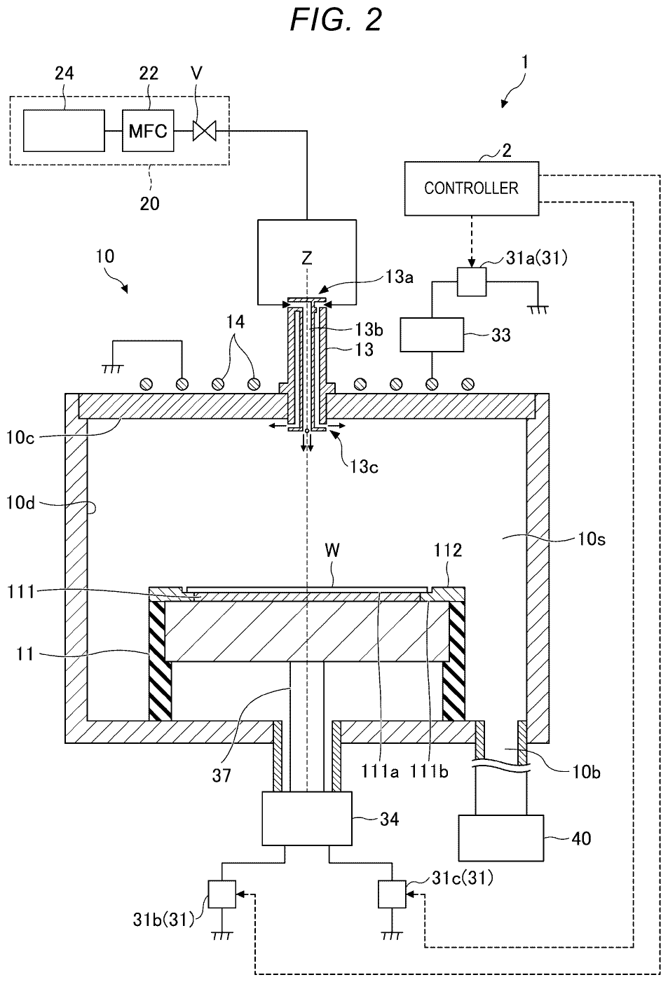

First, a plasma processing system according to an embodiment will be described with reference to FIGS. 1 and 2. FIG. 1 is a diagram illustrating an example of a plasma processing system according to an embodiment. FIG. 2 is a schematic cross-sectional view illustrating an example of a plasma processing apparatus 1 according to the embodiment.

In an embodiment, the plasma processing system includes the plasma processing apparatus 1 and a controller 2. The plasma processing apparatus 1 is configured to supply three radio-frequency power pulses (three RF pulsed signals) into a plasma processing chamber 10, thereby generating a plasma from gas supplied into the plasma processing chamber 10. Then, the plasma processing apparatus 1 exposes the generated plasma to a substrate so as to process the substrate.

The plasma processing apparatus 1 includes the plasma processing chamber 10, a substrate support 11, and a plasma generator 12. The plasma processing chamber 10 has a plasma processing space 10s. In addition, the plasma processing chamber 10 has at least one gas introduction port 13c for supplying at least one processing gas into the plasma processing space 10s, and at least one gas exhaust port 10b for exhausting the gas from the plasma processing space 10s. The gas introduction port 13c is connected to a gas supply 20 which will be described later, and the gas exhaust port 10b is connected to an exhaust system 40 which will be described later. The substrate support 11 is disposed in the plasma processing space 10s and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In the embodiment, an AC signal (AC power) used by the AC plasma generator has a frequency in a range of 100 kHz to 10 GHz. Accordingly, the AC signal includes a radio frequency (RF) signal and a microwave signal. In the embodiment, each of the three RF pulsed signals (a source pulsed signal, a first bias pulsed signal, and a second bias pulsed signal which will be described later) has a frequency in the range of 100 kHz to 150 MHz.

The controller 2 processes computer-executable instructions for instructing the plasma processing apparatus 1 to execute various steps described in the present disclosure. The controller 2 may be configured to control the respective components of the plasma processing apparatus 1 to execute the various steps described herein below. In the embodiment, part or all of the controller 2 may be included in the plasma processing apparatus 1. The controller 2 is implemented by, for example, a computer 21. For example, the controller 2 may include a processor (central processing unit (CPU)) 21a, a storage 21b, and a communication interface 21c. The processing unit 21a may be configured to perform various control operations based on programs stored in the storage 21b. The storage 21b may include a random access memory (RAM), a read only memory (ROM), a hard disk drive (HDD), a solid state drive (SSD), or a combination thereof. The communication interface 21c may communicate with the plasma processing apparatus 1 via a communication line such as a local area network (LAN).

Hereinafter, a configuration example of the inductively-coupled plasma processing apparatus 1 as an example of the plasma processing apparatus 1 will be described with reference to FIG. 2.

The inductively-coupled plasma processing apparatus 1 includes the plasma processing chamber 10, the gas supply 20, a power supply, and the exhaust system 40. The plasma processing chamber 10 includes a dielectric window 10c and a sidewall 10d. Further, the plasma processing apparatus 1 includes the substrate support 11, a gas introduction unit, and an antenna 14. The antenna 14 is disposed on the plasma processing chamber 10 (that is, the dielectric window 10c). The plasma processing chamber 10 has the plasma processing space 10s defined by the dielectric window 10c, the sidewall 10d of the plasma processing chamber 10, the substrate support 11, and a bottom wall.

The substrate support 11 includes a main body 111 and a ring assembly 112. The main body 111 has a central region (substrate support surface) 111a for supporting the substrate (wafer) W, and an annular region (ring support surface) 111b for supporting the ring assembly 112. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. In the embodiment, the main body 111 includes a base and an electrostatic chuck. The base includes a conductive member. The conductive member of the base functions as a lower electrode. The electrostatic chuck is disposed on the base. The upper surface of the electrostatic chuck has a substrate support surface 111a. The ring assembly 112 includes one or more annular members. At least one of the one or more annular members is an edge ring. Although not illustrated, the substrate support 11 may include a temperature control module configured to adjust at least one of the electrostatic chuck, the ring assembly 112, and the substrate to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas between the rear surface of the substrate W and the substrate support surface 111a.

The gas introduction unit is configured to introduce at least one processing gas from the gas supply 20 into the plasma processing space 10s. In the embodiment, the gas introduction unit includes a center gas injector (CGI) 13. The center gas injector 13 is disposed above the substrate support 11 and attached to a center opening formed in the dielectric window 10c. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s from the gas introduction port 13c. The gas introduction unit may include one or more side gas injectors (SGI) attached to one or more openings formed in the sidewall 10d, in addition to or instead of the center gas injector 13.

The gas supply 20 may include at least one gas source 24 and at least one flow rate controller 22. In the embodiment, the gas supply 20 is configured to supply at least one processing gas from the respective corresponding gas sources 24 to the gas introduction unit via the respective corresponding flow rate controller 22 and an opening/closing valve V. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power supply includes an RF power supply 31 coupled to the plasma processing chamber 10 via at least one impedance matching circuit. The RF power supply 31 is configured to supply three RF signals (RF powers) of the source pulsed signal and the first and second bias pulsed signals to the conductive member of the substrate support 11 and/or the antenna 14. As a result, plasma is formed from at least one processing gas supplied into the plasma processing space 10s. Accordingly, the RF power supply 31 may function as at least a part of the plasma generator 12. Further, by supplying either the first bias pulsed signal or the second bias pulsed signal to the conductive member of the substrate support 11, a bias potential is generated in the substrate W, and ions in the formed plasma can be attracted into the substrate W.

In the embodiment, the RF power supply 31 includes a source generator 31a, a first bias generator 31b, and a second bias generator 31c. The source generator 31a (first power source) is coupled to the antenna 14 via at least one impedance matching circuit, and is configured to generate a source pulsed signal and supply the source pulsed signal to the antenna 14. The source generator 31a is coupled to the antenna 14 via an impedance matching circuit 33. In the embodiment, the source pulsed signal has a frequency in a range of 13 MHz to 150 MHz. In the embodiment, the source generator 31a may be configured to generate source pulsed signals having different frequencies. The generated one or more source pulsed signals are supplied to the antenna 14. The first power source is configured to supply a first electric signal to the antenna 14, and the first electric signal (source pulsed signal) includes a first RF signal having a first RF frequency.

In the embodiment, the first bias generator 31b (the second power source) is coupled to the conductive member of the substrate support 11 via at least one impedance matching circuit, and configured to generate the first bias pulsed signal to supply the first bias pulsed signal to the substrate support 11. The first bias generator 31b is coupled to the substrate support 11 via an impedance matching circuit 34. In the embodiment, the first bias pulsed signal has a frequency lower than the frequency of the source pulsed signal. In the embodiment, the first bias pulsed signal has a frequency in a range of 100 kHz to 60 MHz. An example of the frequency of the first bias pulsed signal includes 40 MHz or 60 MHz. The second power source is configured to supply a second electric signal to at least one electrode, and the second electric signal (the first bias pulsed signal) includes a second RF signal having a second RF frequency.

In the embodiment, the first bias generator 31b may be configured to generate first bias pulsed signals having different frequencies. The generated one or more first bias pulsed signals are supplied to the conductive member of the substrate support 11.

In the embodiment, the second bias generator 31c (the third power source) is coupled to the conductive member of the substrate support 11 via at least one impedance matching circuit, and is configured to generate a second bias pulsed signal to supply the second bias pulsed signal to the substrate support 11. The second bias generator 31c is coupled to the substrate support 11 via the impedance matching circuit 34. In the embodiment, the second bias pulsed signal has a frequency in a range of 100 kHz to 13.56 MHz, and the frequency thereof is lower than the frequency of the first bias pulsed signal. The third power source is configured to supply a third electric signal to at least one electrode, and the third electric signal (the second bias pulsed signal) includes a third RF signal or a DC signal having a third RF frequency lower than the first RF frequency and the second RF frequency.

In the embodiment, the second bias generator 31c may be configured to generate second bias pulsed signals having different frequencies. The generated one or more second bias pulsed signals are supplied to the conductive member of the substrate support 11. Further, in various embodiments, the source pulsed signal, the first bias pulsed signal, and the second bias pulsed signal are radio frequency (RF) signals.

The antenna 14 includes one or more coils. In an embodiment, the antenna 14 may include an outer coil and an inner coil that are coaxially arranged. In this case, the RF power supply 31 may be connected to both the outer coil and the inner coil, or may be connected to either the outer coil or the inner coil. In the former case, the same source generator 31a may be connected to both the outer coil and the inner coil, and separate source generators 31a may be connected to the outer coil and the inner coil, respectively.

The exhaust system 40 may be connected to, for example, a gas exhaust port 10b disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

### [Example of Internal Configuration of Impedance Matching Circuit]

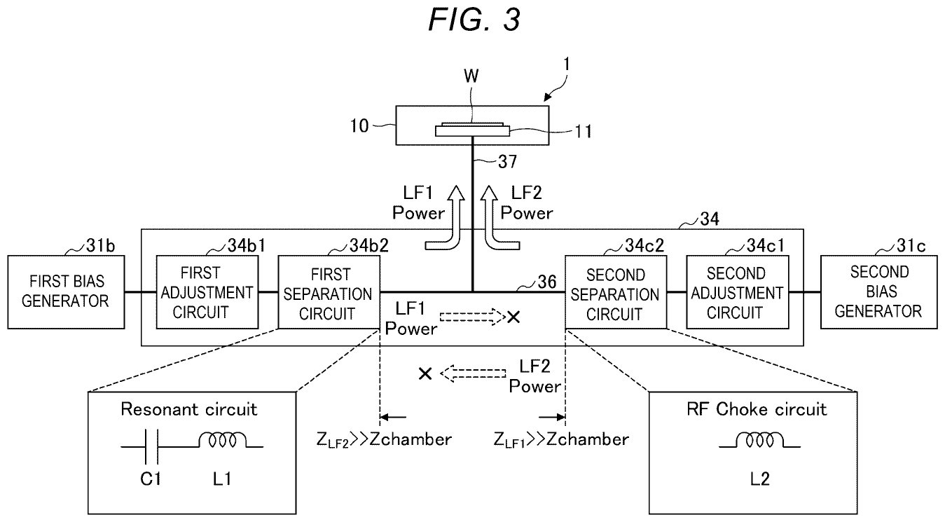

Next, an example of a configuration of the impedance matching circuit 34 will be described with reference to FIG. 3. FIG. 3 is a view illustrating an example of an internal configuration of the impedance matching circuit 34 according to the embodiment.

The first bias generator 31b and the second bias generator 31c are connected to the conductive member of the substrate support 11 via the impedance matching circuit 34 and a power feeding line 37. The first bias pulsed signal supplied from the first bias generator 31b will also be referred to as LF1 power in the following descriptions. Further, the second bias pulsed signal supplied from the second bias generator 31c will also be referred to as LF2 power in the following descriptions.

When the first bias pulsed signal (the LF1 power) supplied from the first bias generator 31b is coupled to an opposite side (the second bias generator 31c side) via a power feeding line 36 in the impedance matching circuit 34, supply efficiency of the LF1 power supplied to the plasma processing chamber 10 is deteriorated. Similarly, when the second bias pulsed signal (the LF2 power) supplied from the second bias generator 31c is coupled to an opposite side (the first bias generator 31b side) via the power feeding line 36, supply efficiency of the LF2 power supplied to the plasma processing chamber 10 is deteriorated. Then, since the supply of the bias power to the plasma processing chamber 10 is reduced, it becomes difficult to control the ion energy or the like, and the process performance is deteriorated.

Thus, the impedance matching circuit 34 according to the present embodiment includes a first adjustment circuit 34b1, a first separation circuit 34b2, a second adjustment circuit 34c1, and a second separation circuit 34c2. The first adjustment circuit 34b1 and the first separation circuit 34b2 are connected between the first bias generator 31b and the power feeding line 37. The second adjustment circuit 34c1 and the second separation circuit 34c2 are connected between the second bias generator 31c and the power feeding line 37. With this configuration, the first bias pulsed signal (the LF1 power) generated in the first bias generator 31b is supplied to the conductive member of the substrate support 11 while being suppressed from being coupled to the second bias generator 31c. Further, the second bias pulsed signal (the LF2 power) generated in the second bias generator 31c is supplied to the conductive member of the substrate support 11 while being suppressed from being coupled to the first bias generator 31b.

The first adjustment circuit 34b1 includes a variable element, and is configured to match the impedance of a load side (the substrate support 11 side) of the first bias generator 31b with the output impedance of the first bias generator 31b. In the embodiment, the variable element of the first adjustment circuit 34b1 is a variable capacitor.

The second separation circuit 34c2 is connected between the second bias generator 31c and the substrate support 11, and suppresses the coupling of the first bias pulsed signal which is the LF1 power from the first bias generator 31b.

The second adjustment circuit 34c1 includes a variable element, and is configured to match the impedance of a load side (the substrate support 11 side) of the second bias generator 31c with the output impedance of the second bias generator 31c. In the embodiment, the variable element of the second adjustment circuit 34c1 is a variable inductor.

The first separation circuit 34b2 is connected between the first bias generator 31b and the substrate support 11, and suppresses the coupling of the second bias pulsed signal which is the LF2 power from the second bias generator 31c.

The second separation circuit 34c2 is an RF choke circuit that includes an inductor L2. The first separation circuit 34b2 is a resonant circuit that includes a capacitor C1 and an inductor L1. The first separation circuit 34b2 is configured by the capacitor C1 and the inductor L1. The second separation circuit 34c2 is configured by the inductor L2.

The first separation circuit 34b2 sets circuit constants of C1 and L1 such that the impedance viewed from the first bias pulsed signal seems to be zero (0) or close to zero (0), and the impedance viewed from the second bias pulsed signal seems to be high and the first bias generator 31b side seems to be a wall. Accordingly, when the impedance of the first separation circuit 34b2 viewed from the second bias pulsed signal is Z_{LF2}, and the load impedance of the plasma is Z_{chamber}, Z_{LF2}>>Z_{chamber} is established.

Further, the second separation circuit 34c2 sets a circuit constant of L2 such that the impedance viewed from the second bias pulsed signal seems to be zero (0) or close to zero (0), and the impedance viewed from the first bias pulsed signal seems to be high and the second bias generator 31c side seems to be a wall. Accordingly, when the impedance viewed from the first bias pulsed signal in the second separation circuit 34c2 is the Z_{LF1}, Z_{LF1}>>Z_{chamber} is established.

By setting the circuit constants of the first separation circuit 34b2 as described above, the impedance Z_{LF2} of the first separation circuit 34b2 becomes much larger than the load impedance Z_{chamber} of the plasma. Accordingly, the first separation circuit 34b2 suppresses the coupling of the second bias pulsed signal from the second bias generator 31c (“LF2 Power→X” in FIG. 3). As a result, the LF2 power is supplied into the plasma processing chamber 10 via the power feeding line 37, so that the deterioration of the supply efficiency of the LF2 power may be suppressed.

Similarly, by setting the circuit constant of the second separation circuit 34c2 as described above, the impedance Z_{LF1} of the second separation circuit 34c2 becomes much larger than the load impedance Z_{chamber} of the plasma. Accordingly, the second separation circuit 34c2 suppresses the coupling of the first bias pulsed signal from the first bias generator 31b (“LF1 Power→X” in FIG. 3). As a result, the LF1 power is supplied into the plasma processing chamber 10 via the power feeding line 37, so that the deterioration of the supply efficiency of the LF1 power may be suppressed.

With this configuration, the pulsed signals of the two bias powers (the LF1 power and the LF2 power) having different frequencies may be efficiently supplied to the substrate support 11.

### [Etching Method]

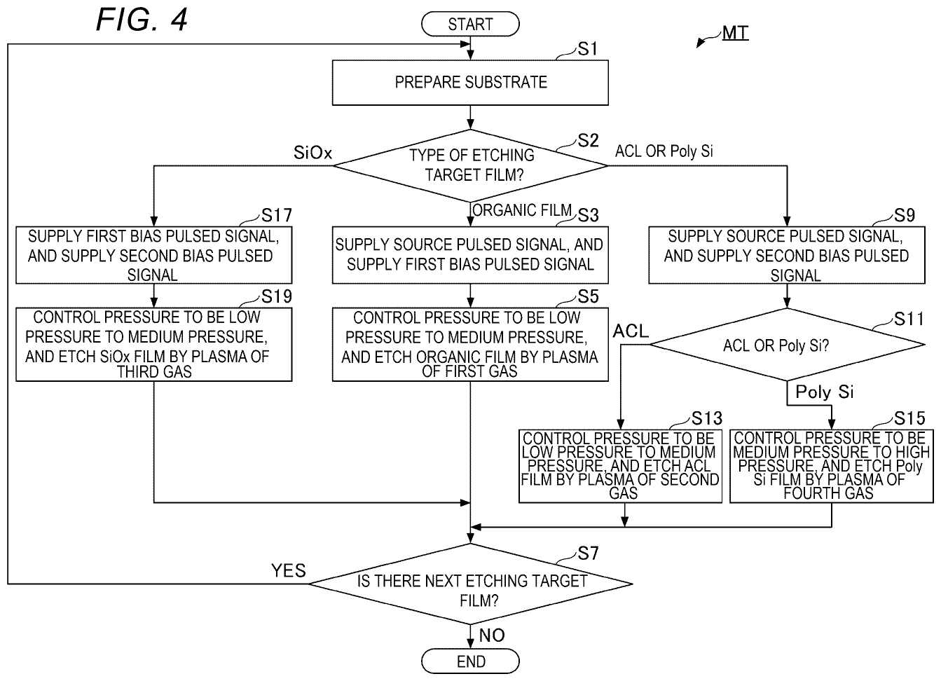

Next, an etching method according to the embodiment will be described with reference to FIG. 4. FIG. 4 illustrates an example of an etching method MT according to the embodiment. The etching method MT is executed by, for example, the plasma processing apparatus 1.

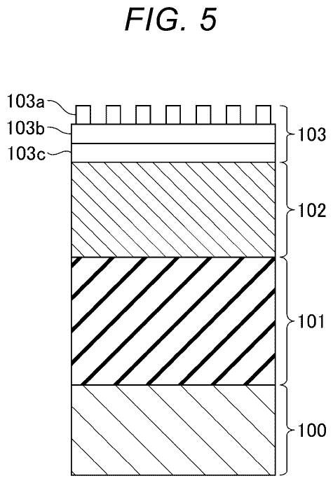

Hereinafter, a stacked film illustrated in FIG. 5 will be described as an etching target film. In the stacked film of FIG. 5, hard masks of a polysilicon film 100 (Poly Si), a silicon oxide film 101 (SiO₂), and an amorphous carbon film 102 (ACL), and a soft mask of an organic film 103 are stacked in this order from the bottom. The organic film has a three-layer structure in which a spin on carbon (SOC) 103c, SiON 103b, and an extreme ultraviolet (EUV) resist film 103a are stacked in this order from the bottom. However, the etching target film is not limited to the stacked film of FIG. 5. Further, the organic film is not limited to three layers, and may be one layer or two or more layers. In the etching method for the stacked film, one plasma processing apparatus 1 can be used to collectively process the stacked film.

The SOC 103c, the SiON 103b, and the resist film 103a are all thin films, and a thickness of the amorphous carbon film 102 and the silicon oxide film 101 is 10 times or more than a thickness of these organic films. Thus, in the amorphous carbon film 102, a deep hole is etched using the organic film 103 as a mask. In the silicon oxide film 101, a deeper hole is etched using the amorphous carbon film 102 as a mask. Therefore, when the silicon oxide film 101 is etched, the ion energy is controlled to be large.

The amorphous carbon film 102 is formed to be thick such that the mask of the amorphous carbon film 102 is not lost before the etching of the silicon oxide film 101 is completed. During the etching, the amorphous carbon film 102 and the silicon oxide film 101 are controlled so as to have a high plasma density and high ion energy. In addition, a plasma of corrosive gas such as Cl₂ gas or HBr gas is required for the polysilicon film 100.

Meanwhile, when the organic film 103 is etched, since the organic film 103 is soft, the ion energy is controlled to be small. As such, the specifications required for each type of the stacked film during the etching are different. Therefore, one plasma processing apparatus cannot collectively process each film of the stacked film, and each film of the stacked film may be necessarily etched using plasma processing apparatuses according to characteristics of each film type.

Therefore, in the etching method according to the present embodiment, the combination of application methods by the source generator 31a, the first bias generator 31b, and the second bias generator 31c is changed. Accordingly, two signals among the three signals of the source pulsed signal, the first bias pulsed signal, and the second bias pulsed signal can be combined. Therefore, it is possible to perform etching on each film of the stacked film in one plasma processing apparatus 1 according to the film type. As a result, it is not necessary to insert or remove the substrate W into or from the plasma processing apparatus 1 according to the film type during the etching, so that productivity may be improved.

In the etching method according to the present embodiment, the plasma processing apparatus 1 may have at least the following (1) to (5).
(1) A high-density plasma generation mechanism (ICP: antenna 14 of an induction coil) or a SWP (surface wave excitation slot antenna) is provided at an upper side of the plasma processing chamber 10. Further, a mechanism for outputting a radio frequency RF (27 MHz or more) and a low frequency RF (2 MHz or less) is provided at a lower side.
(2) An inner wall of the plasma processing chamber 10 is protected by a thermal spray film of yttria or the like so as not to be corroded.
(3) A pre-coating process of SiO₂, carbon, or the like is possible.
(4) A mechanism for outputting a medium frequency RF (13 MHz) can also be added to a lower portion.
(5) A power source capable of outputting at least one pulse to power sources at the upper portion and the lower portion of the RF power supply 31 is provided. Examples of the power sources include the source generator 31a, the first bias generator 31b, and the second bias generator 31c.

The etching method MT executed in the plasma processing apparatus 1 that satisfies the above requirements will be described with reference to FIG. 4. This process is controlled by the controller 2.

When this process is started, in step S1, the controller 2 prepares a substrate on which the stacked film, in which the polysilicon film 100, the silicon oxide film 101, the amorphous carbon film 102, and the organic film 103 illustrated in FIG. 5 are stacked, is formed (referred to as “step a”). Next, in step S2, the controller 2 determines a type of the etching target film. As for the determination of the type of the etching target film, the first film type can be specified as the organic film 103 stacked on the top. As for the next determination of the etching target film, for example, an end point detection method, which uses a spectrometer to detect an end point of the etching, may be used. However, the determination method is not limited thereto.

When it is determined in step S2 that the etching target film is the organic film 103, the process proceeds to step S3, in which the controller 2 supplies the source pulsed signal to the antenna 14, and supplies the first bias pulsed signal to the substrate support 11. Next, in step S5, the controller 2 controls an inside of the plasma processing chamber 10 to a low pressure to a medium pressure, supplies first gas into the plasma processing chamber 10, and etches the organic film 103 on the substrate W by a plasma of the first gas (“step b”). The low pressure is in a range of about 10 m Torr (about 1.33 Pa) to about 20 mTorr (about 2.66 Pa), and the medium pressure is in a range of about 40 mTorr (about 5.33 Pa) to 60 mTorr (about 8.00 Pa). In the etching of the organic film 103, CF-based gas is used as the first gas, and the SiON film 103b and the SOC film 103c are etched in this order in the pattern of the EUV resist film 103a.

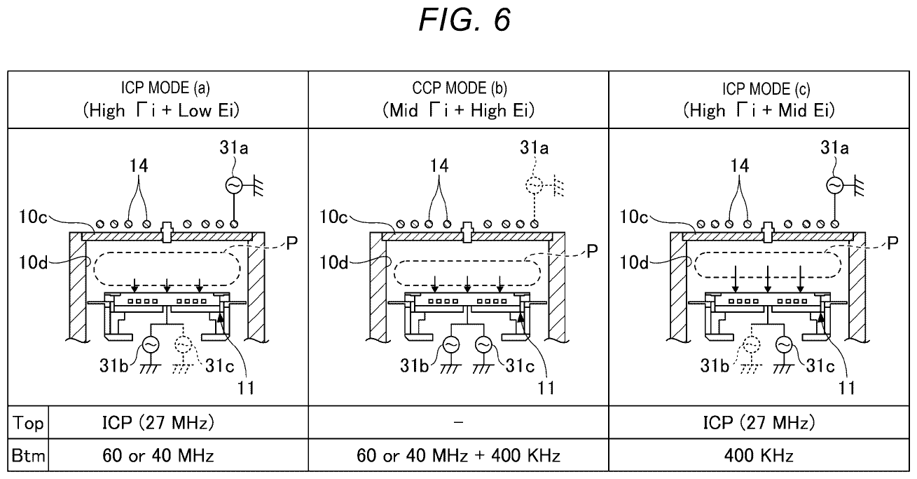

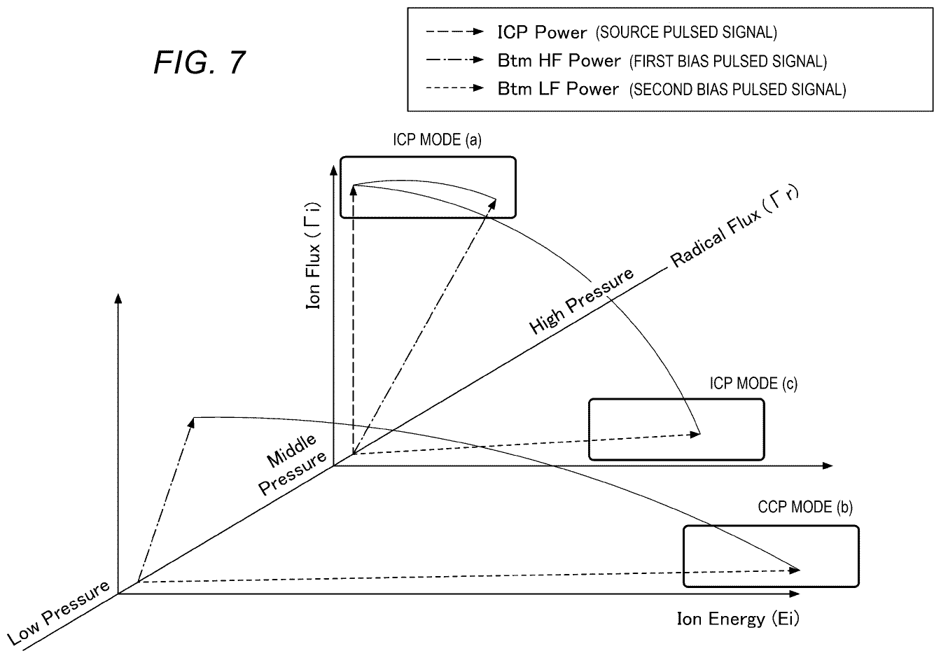

FIG. 6 is a view illustrating an example of application of a pulsed signal according to the etching target film according to the embodiment. FIG. 7 is a view schematically illustrating states of ion flux, ion energy, and radical flux in each mode according to the embodiment. In FIG. 7, a horizontal axis represents ion energy Ei, a vertical axis represents ion flux Γi (the amount of ions), and a diagonal axis represents a pressure (the radical flux). The radical flux is determined by the pressure, and the lower the pressure, the smaller the number of radicals. The ion flux indicates a plasma density.

In steps S3 and S5 of FIG. 4, “ICP mode (a)” of FIGS. 6 and 7 is controlled. This is because the organic film 103 is very soft and thin. Therefore, when the organic film 103 is etched, as illustrated in FIG. 6, a source pulsed signal having a frequency of 27 MHz is supplied from the source generator 31a to the antenna 14, so as to generate a plasma in the ICP mode. Further, a first bias pulsed signal having a frequency of 40 MHz or 60 MHz is supplied from the first bias generator 31b to the substrate support 11. Accordingly, the first bias pulsed signal having a frequency of 40 MHz or 60 MHz can control the self-bias and the ion energy to be lower than the second bias pulsed signal having a frequency of 400 KHz while generating a plasma in the ICP mode. As a result, the attraction of ions can be controlled to be small. Therefore, the plasma density increases due to the plasma generation in the ICP mode, in other words, the ion flux increases and the ion energy decreases as illustrated in “ICP mode (a)” in FIG. 7. Further, by controlling the pressure to be a low pressure to a medium pressure, the radical flux can be controlled to be a low to moderate level. In step S5 of FIG. 4, the controller 2 may control the radical flux to be moderate to high level by controlling the pressure to be a medium pressure to a high pressure. The high pressure is about 100 mTorr (about 13.33 Pa) or more.

When the soft mask such as the organic film 103 is etched as described above, the source pulsed signal is supplied to the antenna 14, and the first bias pulsed signal is supplied to the substrate support 11. However, when the soft mask such as the organic film 103 is etched, only the source pulsed signal or only the first bias pulsed signal may be supplied.

When it is determined in step S2 of FIG. 4 that the type of the etching target film is the amorphous carbon film 102 or the polysilicon film 100, the process proceeds to step S9, in which the controller 2 supplies the source pulsed signal to the antenna 14, and supplies the second bias pulsed signal to the substrate support 11. Next, in step S11, the controller 2 determines whether the type of the etching target film is the amorphous carbon film 102 or the polysilicon film 100. When it is determined that the type of the etching target film is the amorphous carbon film 102, the process proceeds to step S13, and when the type of the etching target film is the polysilicon film 100, the process proceeds to step S15. In step S11, determination can be performed using a spectrometer.

When the film type is the amorphous carbon film 102, in step S13, the controller 2 controls the plasma processing chamber 10 to be a low pressure to a medium pressure, and etches the amorphous carbon film 102 by a plasma of second gas (which is an example of “step c”). In the etching of the amorphous carbon film 102, O₂ gas or CO gas is used as the second gas to etch using the organic film 103 as a mask.

When the film type is the polysilicon film 100, in step S15, the controller 2 controls the plasma processing chamber 10 to be a medium pressure to a high pressure, and etches the polysilicon film 100 on the substrate W by a plasma of fourth gas (which is an example of the “step c”). In the etching of the polysilicon film 100, chlorine gas and bromine gas are used as the fourth gas to etch using the silicon oxide film 101 as a mask.

In steps S9, S13, or S15 of FIG. 4, “ICP mode (c)” of FIGS. 6 and 7 is controlled. As illustrated in FIG. 6, a source pulsed signal having a frequency of 27 MHz is supplied from the source generator 31a to the antenna 14, so as to generate a plasma in the ICP mode. Further, a second bias pulsed signal having a frequency of 400 KHz is supplied from the second bias generator 31c to the substrate support 11. Accordingly, the second bias pulsed signal having a frequency of 400 KHz can control the self-bias and the ion energy to be higher than the first bias pulsed signal having a frequency of 40 MHz while generating a plasma in the ICP mode. As a result, the attraction of ions can be controlled to be large. Accordingly, as illustrated in FIG. 7, the ion energy is increased from a moderate level, and the ion flux is increased. Further, when the amorphous carbon film 102 is etched, the pressure is controlled to be a low pressure to a medium pressure, and the radical flux can be controlled to be in a range of a low to moderate level. In the etching of the amorphous carbon film 102, when the pressure is high, ions enter obliquely, and it becomes difficult to perform deep and thin etching. In order to avoid this problem, in the etching of the amorphous carbon film 102, the pressure is controlled to be a low pressure to a medium pressure. Meanwhile, the etching of the polysilicon film 100 is mainly performed by chemical etching. Therefore, the pressure is controlled to a high pressure (for example, 140 mTorr (18.7 Pa)), the amount of radicals (radical flux) is increased, and the etching is promoted.

When the hard masks such as the amorphous carbon film 102 and the polysilicon film 100 are etched as described above, the source pulsed signal is supplied to the antenna 14, and the second bias pulsed signal is supplied to the substrate support 11.

When it is determined in step S2 of FIG. 4 that the type of the etching target film is the silicon oxide film 101, the process proceeds to step S17, and the controller 2 supplies the first bias pulsed signal and the second bias pulsed signal to the substrate support 11. Next, in step S19, the controller 2 controls the plasma processing chamber 10 to be a low pressure to a medium pressure, and etches the silicon oxide film 101 on the substrate W by a plasma of the third gas (“step d”). In the etching of the silicon oxide film 101, CF-based gas is used as the third gas to etch using the amorphous carbon film 102 as a mask.

In steps S17 and S19 of FIG. 4, “CCP mode (b)” of FIGS. 6 and 7 is controlled. As illustrated in FIG. 6, the first bias pulsed signal having a frequency of 40 MHz or 60 MHz is supplied from the first bias generator 31b to the substrate support 11, and generates a plasma in a CCP mode. Further, a second bias pulsed signal having a frequency of 400 KHz is supplied from the second bias generator 31c to the substrate support 11. Accordingly, since the source pulsed signal is not supplied to the antenna 14, power applied to the upper portion of the plasma processing chamber 10 becomes zero (0), so that the capacity-coupled (CCP mode) control is performed. A first bias pulsed signal having a frequency of 40 MHz or 60 MHz and a second bias pulsed signal having a frequency of 400 KHz are supplied to the substrate support 11 while being superimposed. Therefore, as illustrated in the CCP mode (b) of FIG. 7, the ion energy is larger than that of the ICP modes (a) and (c) and has very high ion energy. Since the pressure is controlled from a low pressure to a medium pressure, the ion flux is moderate. As a result, a moderate amount of ions are attracted at very high ion energy, and the silicon oxide film 101 is etched by the ion energy.

In generation of a plasma having two frequencies in the lower portion by the first bias pulsed signal and the second bias pulsed signal in the CCP mode (b), a plasma is mainly generated by the first bias pulsed signal having a frequency of 40 MHz or 60 MHz. A generation position of the plasma generated at this time is lower (close to the substrate support 11) than in the ICP modes (a) and (c). Therefore, it is easier to be lost than the plasma generated in the upper portion as in the ICP modes (a) and (c), and a part of the plasma is consumed and lost in the substrate support 11 or a sidewall of the plasma processing chamber 10. Therefore, plasma generation efficiency is lower than that in the ICP mode (a). As a result, in the ICP modes (a) and (c), a high-density plasma is obtained, and the ion flux is increased. In the CCP mode (b), a medium-density plasma is obtained, and the ion flux is moderate. Further, the pressure is controlled to a low pressure of about 10 mTorr, and the incidence of ions is controlled to be substantially vertical. In order to form a deep hole by etching, the radical flux that promotes chemical etching is not necessarily required, and the ion energy is required.

Accordingly, in the etching of the silicon oxide film 101 having a high aspect, the first bias pulsed signal of 40 MHz or 60 MHz and the second bias pulsed signal of 400 KHz are used. The first bias pulsed signal of 40 MHz or 60 MHz contributes to the plasma generation. The second bias pulsed signal of 400 KHz efficiently attracts ions from the plasma.

As described above, according to the etching method MT, the ICP mode (a), the ICP mode (c), and the CCP mode (b) are used separately for each film type. In this way, it is possible to optimally switch the frequency of the pulsed signal for supplying the power, according to characteristics of the film type.

In “step b” of controlling the ICP mode (a), the source pulsed signal is supplied to the antenna 14, and the first bias pulsed signal is supplied to the substrate support 11 to etch the organic film 103.

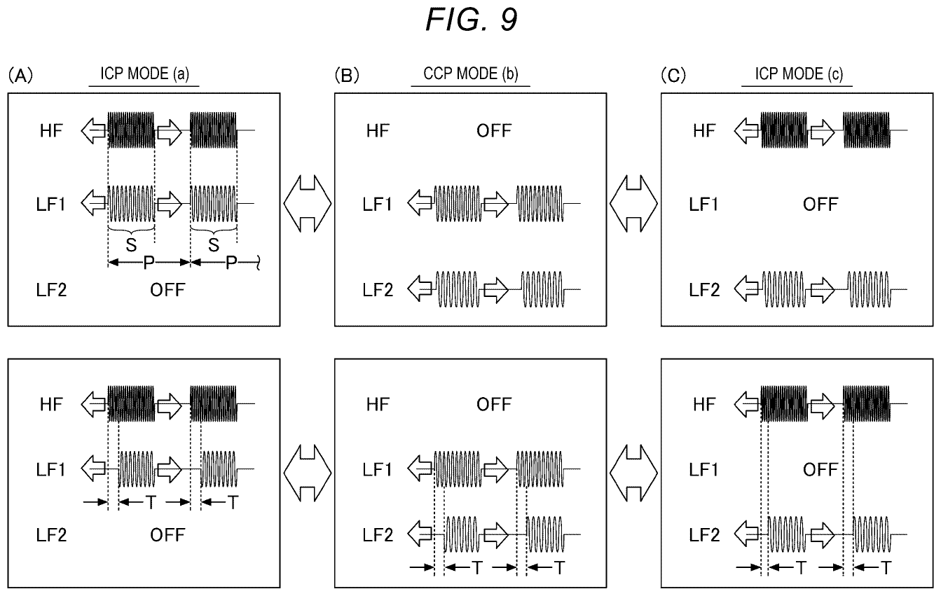

The ICP mode (a) of (A) of FIG. 9 is an example of a first plasma processing mode. In the first plasma processing mode, a first electric signal denoted as HF is supplied to the antenna, and a second electric signal denoted as LF1 is supplied to at least one electrode, without supplying a third electric signal denoted as LF2 in FIG. 9 to at least one electrode. “Step b” is an example of a step performed in the first plasma processing mode. In the first plasma processing mode, as illustrated in a lower part of (A) of FIG. 9, the second electric signal denoted as LF1 may be supplied to at least one electrode as delaying by offset time T with regard to the first electric signal denoted as HF.

In “step c” of controlling the ICP mode (c), the source pulsed signal is supplied to the antenna 14, and the second bias pulsed signal is supplied to the substrate support 11 to etch the amorphous carbon film 102 and the polysilicon film 100.

The ICP mode (c) of (C) of FIG. 9 is an example of a second plasma processing mode. In the second plasma processing mode, the first electric signal denoted as HF is supplied to the antenna, and a third electric signal denoted as LF2 is supplied to at least one electrode, without supplying the second electric signal denoted as LF1 to at least one electrode. “Step c” is an example of a step performed in the second plasma processing mode. In the second plasma processing mode, as illustrated in a lower part of (C) of FIG. 9, the third electric signal denoted as LF2 may be supplied to at least one electrode as delaying by offset time T with regard to the first electric signal denoted as HF.

In “step d” of controlling the CCP mode (b), the first bias pulsed signal and the second bias pulsed signal are supplied to the substrate support 11 to etch the silicon oxide film 101.

The CCP mode (b) of (B) of FIG. 9 is an example of a third plasma processing mode. In the third plasma processing mode, the second electric signal denoted as LF1 and the third electric signal denoted as LF2 are supplied to at least one electrode, without supplying the first electric signal denoted as HF to the antenna. “Step d” is an example of a step performed in the third plasma processing mode. As illustrated in a lower part of (B) of FIG. 9, the third electric signal denoted as LF2 may be supplied to at least one electrode as delaying by offset time T with regard to the second electric signal denoted as LF1.

The controller 2 is configured to control the first power source, the second power source, and the third power source so as to selectively execute the first plasma processing mode, the second plasma processing mode, and the third plasma processing mode. The first plasma processing mode and the second plasma processing mode are inductively coupled plasma processing modes, and the third plasma processing mode is a capacitively coupled plasma processing mode.

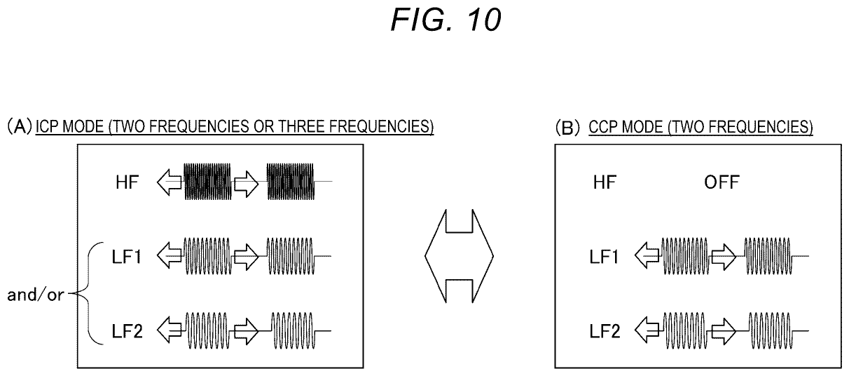

The third electric signal denoted as LF2 may include a third RF signal. In the ICP mode, as illustrated in (A) of FIG. 10, three signals of the first RF signal, the second RF signal, and the third RF signal may be supplied, two signals of the first RF signal and the second RF signal may be supplied, or two signals of the first RF signal and the third RF signal may be supplied. The first RF signal, the second RF signal, and the third RF signal may be pulsed. In (A) of FIG. 10, ON/OFF states of three RF signals HF, LF1, and LF2 are repeated in synchronization with each other in a predetermined repetition period. In the CCP mode, as illustrated in (B) of FIG. 10, two signals of the second RF signal and the third RF signal may be supplied. The second RF signal and the third RF signal may be pulsed. In (B) of FIG. 10, ON/OFF states of two RF signals LF1 and LF2 are repeated in a predetermined repetition period.

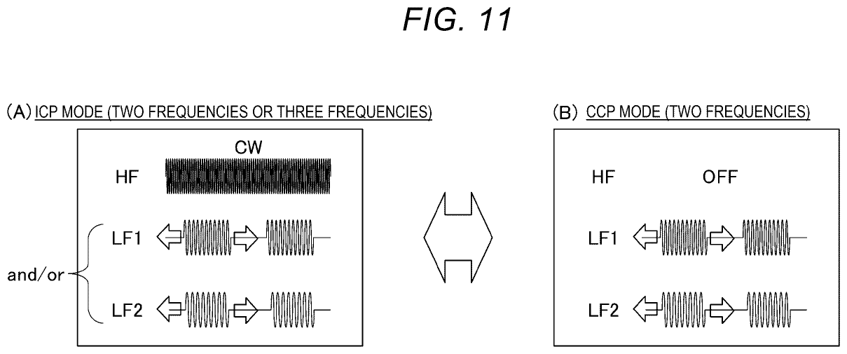

The third RF frequency may be in a range of 100 kHz to 13.56 MHz. The third electric signal may include the third RF signal, the first RF signal denoted as HF may be a continuous wave as illustrated in (A) of FIG. 11, and the second RF signal and the third RF signal may be pulsed. The third electric signal may include a DC signal, and the DC signal may include a sequence of pulses having a first voltage level during a first state of the repetition period. Instead of the RF signal of the LF1 illustrated in (A) of FIG. 9, the DC signal may be supplied. The DC signal may include a sequence S of pulses having the first voltage level during the first state of a repetition period P. The RF signal of the LF2 may also be supplied with the DC signal instead of the RF signal. The DC signal may include a sequence of pulses having the first voltage level during the first state of the repetition period.

The first voltage level may have a negative polarity. The sequence of pulses may be in a range of 100 kHz to 1 MHz. The DC signal may have a second voltage level during a second state of the repetition period, and an absolute value of the second voltage level may be smaller than an absolute value of the first voltage level. At least one electrode may include a first electrode, and the second electric signal and the third electric signal may be supplied to the first electrode. At least one electrode may include the first electrode and the second electrode, the second electric signal may be supplied to the first electrode, and the third electric signal may be supplied to the second electrode.

“Step b” and “step c” are examples of the inductively coupled plasma processing mode. In the inductively coupled plasma processing mode, the first electric signal is supplied to the antenna, and the second electric signal and/or the third electric signal is supplied to at least one electrode.

“Step d” is an example of the capacitively coupled plasma processing mode. In the capacitively coupled plasma processing mode, the second electric signal and the third electric signal are supplied to at least one electrode without supplying the first electric signal to the antenna.

The controller 2 is configured to control the first power source, the second power source, and the third power source to selectively execute the inductively coupled plasma processing mode and the capacitively coupled plasma processing mode.

The third electric signal may include the third RF signal, and the first RF signal, the second RF signal, and the third RF signal may be pulsed. The third RF frequency may be in a range of 100 kHz to 13.56 MHz. The third electric signal may include the third RF signal, the first RF signal may be a continuous wave, and the second RF signal and the third RF signal may be pulsed. The third electric signal may include a DC signal, and the DC signal may include a sequence of pulses having a first voltage level during a first state of the repetition period. The first voltage level may have a negative polarity. The sequence of pulses may have a pulse frequency in a range of 100 kHz to 1 MHz. The DC signal may have a second voltage level during a second state of the repetition period, and an absolute value of the second voltage level may be smaller than an absolute value of the first voltage level. At least one electrode may include a first electrode, and the second electric signal and the third electric signal may be supplied to the first electrode.

The etching method according to the present embodiment can be applied when etching the stacked film including at least two of an organic film, the silicon nitride film (SiN), a carbon film such as amorphous carbon, a silicon oxide film, and a polysilicon film. For example, the organic film is etched under the control of “step b”. The silicon oxide film and the silicon nitride film are etched under the control of “step d”. The carbon film and the polysilicon film are etched under the control of “step c”.

According to the type of the etching target film included in the stacked film, at least one of “step b” and “step c” is switched to “step d” and executed. As a result, one plasma processing apparatus 1 can collectively process the stacked film including at least two of an organic film, the silicon nitride film (SiN), a carbon film such as amorphous carbon, a silicon oxide film, and a polysilicon film.

### [Other]

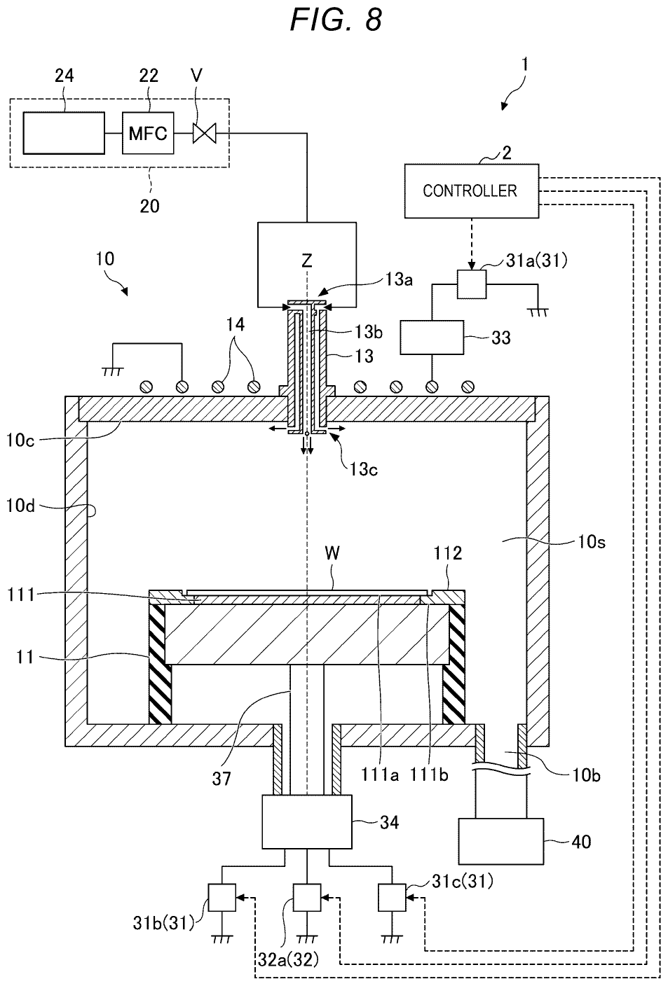

The second bias pulsed signal may be a DC signal. The DC signal may have a pulse waveform of a rectangle, or may have a pulse waveform of a rectangle, a trapezoid, a triangle, or a combination thereof. As illustrated in FIG. 8, the plasma processing apparatus 1 may include a DC power source 32 coupled to the plasma processing chamber 10. The DC power source 32 includes a bias DC generator 32a. In the embodiment, the bias DC generator 32a is connected to the conductive member of the substrate support 11 and is configured to generate a DC signal. The generated DC signal is applied to the conductive member of the substrate support 11. In the embodiment, the DC signal may be applied to another electrode, such as an electrode in an electrostatic chuck. The bias DC generator 32a may be provided in addition to the RF power supply 31, or may be provided instead of the second bias generator 31c.

As described above, according to the etching method and the plasma processing apparatus 1 of the present embodiment, it is possible to perform etching according to the film types in one plasma processing apparatus. The etching method and the plasma processing apparatus according to the embodiment disclosed herein are illustrative and should not be construed as being limited in all aspects. Various modifications and improvements can be made to the embodiments without departing from the spirit and scope of the appended claims. The aspects disclosed in the above embodiments also can have the other configurations to the extent not conflict, and can be combined with each other to the extent not conflict.

The embodiments disclosed above include, for example, the following aspects.

### Appendix 1

An etching method that is used in a plasma processing apparatus including
a plasma processing chamber,
a substrate support provided in the plasma processing chamber,
an antenna provided above the plasma processing chamber,
a source generator configured to generate a source pulsed signal to supply the source pulsed signal to the antenna,
a first bias generator configured to generate a first bias pulsed signal to supply the first bias pulsed signal to the substrate support, and to supply the first bias pulsed signal at a frequency lower than a frequency of the source pulsed signal, and
a second bias generator configured to generate a second bias pulsed signal to supply the second bias pulsed signal to the substrate support, and to supply the second bias pulsed signal at a frequency lower than the frequency of the first bias pulsed signal, the etching method including:
(a) preparing a substrate on which a stacked film including a plurality of types of films is formed;
(b) supplying the source pulsed signal to the antenna, and supplying the first bias pulsed signal to the substrate support to etch the substrate;
(c) supplying the source pulsed signal to the antenna, and supplying the second bias pulsed signal to the substrate support to etch the substrate; and
(d) supplying the first bias pulsed signal and the second bias pulsed signal to the substrate support to etch the substrate.

### Appendix 2

The etching method according to Appendix 1, further including (e) determining the type of a film that is an etching target among the films included in the stacked film,
in which according to the type of the film determined in (e), at least one of (b) and (c) is switched to (d) and executed.

### Appendix 3

The etching method according to Appendix 1 or 2, in which (b), (c), and (d) are executable in the same plasma processing chamber.

### Appendix 4

The etching method according to any one of Appendices 1 to 3,
in which in the stacked film, a polysilicon film, a silicon oxide film, an amorphous carbon film, and an organic film are stacked in this order from a bottom,
in (b), the organic film is etched,
in (c), the amorphous carbon film and the polysilicon film is etched, and
in (d), the silicon oxide film is etched.

### Appendix 5

The etching method according to Appendix 4, in which the organic film includes three layers of spin on carbon (SOC), SiON, and extreme ultraviolet (EUV) in this order from the bottom.

### Appendix 6

The etching method according to any one of Appendices 1 to 5, in which the source pulsed signal, the first bias pulsed signal, and the second bias pulsed signal are radio frequency (RF) signals.

### Appendix 7

The etching method according to any one of Appendices 1 to 6, in which the second bias pulsed signal is a DC signal.

### Appendix 8

A plasma processing apparatus including:
a plasma processing chamber;
a substrate support provided in the plasma processing chamber;
an antenna provided above the plasma processing chamber;
a source generator configured to generate a source pulsed signal to supply the source pulsed signal to the antenna;
a first bias generator configured to generate a first bias pulsed signal to supply the first bias pulsed signal to the substrate support, and to supply the first bias pulsed signal at a frequency lower than a frequency of the source pulsed signal;
a second bias generator configured to generate a second bias pulsed signal to supply the second bias pulsed signal to the substrate support, and to supply the second bias pulsed signal at a frequency lower than the frequency of the first bias pulsed signal; and
a controller,
in which the controller controls the steps of:
(a) preparing a substrate on which a stacked film including a plurality of types of films is formed;
(b) supplying the source pulsed signal to the antenna, and supplying the first bias pulsed signal to the substrate support to etch the substrate;
(c) supplying the source pulsed signal to the antenna, and supplying the second bias pulsed signal to the substrate support to etch the substrate; and
(d) supplying the first bias pulsed signal and the second bias pulsed signal to the substrate support to etch the substrate.

Moreover, the embodiments disclosed above include, for example, the following aspects.

### Appendix 1

A plasma processing apparatus including:
a plasma processing chamber;
a substrate support disposed in the plasma processing chamber and including at least one electrode;
an antenna disposed above the plasma processing chamber;
a first power source configured to supply a first electric signal to the antenna, the first electric signal including a first RF signal having a first RF frequency;
a second power source configured to supply a second electric signal to the at least one electrode, the second electric signal including a second RF signal having a second RF frequency;
a third power source configured to supply a third electric signal to the at least one electrode, the third electric signal including a third RF signal or a DC signal having a third RF frequency that is lower than the first RF frequency and the second RF frequency; and
a controller configured to control the first power source, the second power source, and the third power source so as to selectively execute a first plasma processing mode, a second plasma processing mode, and a third plasma processing mode,
in which in the first plasma processing mode, the third electric signal is not supplied to the at least one electrode, the first electric signal is supplied to the antenna, and the second electric signal is supplied to the at least one electrode,
in the second plasma processing mode, the second electric signal is not supplied to the at least one electrode, the first electric signal is supplied to the antenna, and the third electric signal is supplied to the at least one electrode, and
in the third plasma processing mode, the first electric signal is not supplied to the antenna, and the second electric signal and the third electric signal are supplied to the at least one electrode.

### Appendix 2

The plasma processing apparatus according to Appendix 1,
in which the first plasma processing mode and the second plasma processing mode are inductively coupled plasma processing modes, and
the third plasma processing mode is a capacitively coupled plasma processing mode.

### Appendix 3

The plasma processing apparatus according to Appendix 1 or 2,
in which the third electric signal includes the third RF signal, and
the first RF signal, the second RF signal, and the third RF signal are pulsed.

### Appendix 4

The plasma processing apparatus according to any one of Appendices 1 to 3, in which the third RF frequency is in a range of 100 kHz to 13.56 MHz.

### Appendix 5

The plasma processing apparatus according to any one of Appendices 1 to 4,
in which the third electric signal includes the third RF signal,
the first RF signal is a continuous wave, and
the second RF signal and the third RF signal are pulsed.

### Appendix 6

The plasma processing apparatus according to any one of Appendices 1 to 5,
in which the third electric signal includes the DC signal, and
the DC signal includes a sequence of pulses having a first voltage level during a first state of a repetition period.

### Appendix 7

The plasma processing apparatus according to Appendix 6, in which the first voltage level has a negative polarity.

### Appendix 8

The plasma processing apparatus according to Appendix 6 or 7, in which the sequence of pulses has a pulse frequency in a range of 100 kHz to 1 MHz.

### Appendix 9

The plasma processing apparatus according to Appendix 8, in which the DC signal has a second voltage level during a second state of the repetition period, and an absolute value of the second voltage level is smaller than an absolute value of the first voltage level.

### Appendix 10

The plasma processing apparatus according to any one of Appendices 1 to 9,
in which the at least one electrode includes a first electrode, and
the second electric signal and the third electric signal are supplied to the first electrode.

### Appendix 11

The plasma processing apparatus according to any one of Appendices 1 to 9,
in which the at least one electrode includes a first electrode and a second electrode,
the second electric signal is supplied to the first electrode, and
the third electric signal is supplied to the second electrode.

### Appendix 12

A plasma processing apparatus including:
a plasma processing chamber;
a substrate support disposed in the plasma processing chamber and including at least one electrode;
an antenna disposed above the plasma processing chamber;
a first power source configured to supply a first electric signal to the antenna, the first electric signal including a first RF signal having a first RF frequency;
a second power source configured to supply a second electric signal to the at least one electrode, the second electric signal including a second RF signal having a second RF frequency;
a third power source configured to supply a third electric signal to the at least one electrode, the third electric signal including a third RF signal or a DC signal having a third RF frequency that is lower than the first RF frequency and the second RF frequency; and
a controller configured to control the first power source, the second power source, and the third power source so as to selectively execute an inductively coupled plasma processing mode and a capacitively coupled plasma processing mode,
in which in the inductively coupled plasma processing mode, the first electric signal is supplied to the antenna, and the second electric signal and/or the third electric signal is supplied to the at least one electrode, and
in the capacitively coupled plasma processing mode, the first electric signal is not supplied to the antenna, and the second electric signal and the third electric signal are supplied to the at least one electrode.

### Appendix 13

The plasma processing apparatus according to Appendix 12,
in which the third electric signal includes the third RF signal, and
the first RF signal, the second RF signal, and the third RF signal are pulsed.

### Appendix 14

The plasma processing apparatus according to Appendix 12 or 13, in which the third RF frequency is in a range of 100 kHz to 13.56 MHz.

### Appendix 15

The plasma processing apparatus according to any one of Appendices 12 to 14,
in which the third electric signal includes the third RF signal,
the first RF signal is a continuous wave, and
the second RF signal and the third RF signal are pulsed.

### Appendix 16

The plasma processing apparatus according to any one of Appendices 12 to 15,
in which the third electric signal includes the DC signal, and
the DC signal includes a sequence of pulses having a first voltage level during a first state of a repetition period.

### Appendix 17

The plasma processing apparatus according to Appendix 16, in which the first voltage level has a negative polarity.

### Appendix 18

The plasma processing apparatus according to Appendix 16 or 17, in which the sequence of pulses has a pulse frequency in a range of 100 kHz to 500 kHz.

### Appendix 19

The plasma processing apparatus according to Appendix 18, in which the DC signal has a second voltage level during a second state of the repetition period, and an absolute value of the second voltage level is smaller than an absolute value of the first voltage level.

### Appendix 20

The plasma processing apparatus according to any one of Appendices 12 to 19,
in which the at least one electrode includes a first electrode, and
the second electric signal and the third electric signal are supplied to the first electrode.

The present application is based upon and claims priority to basic application No. 2021-150606, filed with the Japan Patent Office on Sep. 15, 2021, the entire contents of which are incorporated herein by reference.

1. A plasma processing apparatus comprising:
a plasma processing chamber;
a substrate support disposed in the plasma processing chamber and including at least one electrode;
an antenna disposed above the plasma processing chamber;
a first power source configured to supply a first electric signal to the antenna, the first electric signal including a first RF signal having a first RF frequency;
a second power source configured to supply a second electric signal to the at least one electrode, the second electric signal including a second RF signal having a second RF frequency;
a third power source configured to supply a third electric signal to the at least one electrode, the third electric signal including a third RF signal or a DC signal having a third RF frequency that is lower than the first RF frequency and the second RF frequency; and
a controller that includes a processor that is configured by execution of computer readable instructions stored in a computer-readable storage to control the first power source, the second power source, and the third power source so as to selectively execute a first plasma processing mode, a second plasma processing mode, and a third plasma processing mode,
wherein in the first plasma processing mode, the third electric signal is not supplied to the at least one electrode, the first electric signal is supplied to the antenna, and the second electric signal is supplied to the at least one electrode,
in the second plasma processing mode, the second electric signal is not supplied to the at least one electrode, the first electric signal is supplied to the antenna, and the third electric signal is supplied to the at least one electrode, and
in the third plasma processing mode, the first electric signal is not supplied to the antenna, and the second electric signal and the third electric signal are supplied to the at least one electrode.

2. The plasma processing apparatus according to claim 1,
wherein the first plasma processing mode and the second plasma processing mode are inductively coupled plasma processing modes, and
the third plasma processing mode is a capacitively coupled plasma processing mode.

3. The plasma processing apparatus according to claim 1,
wherein the third electric signal includes the third RF signal, and
the first RF signal, the second RF signal, and the third RF signal are pulsed.

4. The plasma processing apparatus according to claim 3,
wherein the third RF frequency is in a range of 100 kHz to 13.56 MHz.

5. The plasma processing apparatus according to claim 1,
wherein the third electric signal includes the third RF signal,
the first RF signal is a continuous wave, and
the second RF signal and the third RF signal are pulsed.

6. The plasma processing apparatus according to claim 1,
wherein the third electric signal includes the DC signal, and
the DC signal includes a sequence of pulses having a first voltage level during a first state of a repetition period.

7. The plasma processing apparatus according to claim 6,
wherein the first voltage level has a negative polarity.

8. The plasma processing apparatus according to claim 7,
wherein the sequence of pulses has a pulse frequency in a range of 100 kHz to 1 MHz.

9. The plasma processing apparatus according to claim 8,
wherein the DC signal has a second voltage level during a second state of the repetition period, and an absolute value of the second voltage level is smaller than an absolute value of the first voltage level.

10. The plasma processing apparatus according to claim 1,
wherein the at least one electrode includes a first electrode, and
the second electric signal and the third electric signal are supplied to the first electrode.

11. The plasma processing apparatus according to claim 1,
wherein the at least one electrode includes a first electrode and a second electrode,
the second electric signal is supplied to the first electrode, and
the third electric signal is supplied to the second electrode.

12. A plasma processing apparatus comprising:
a plasma processing chamber;
a substrate support disposed in the plasma processing chamber and including at least one electrode;
an antenna disposed above the plasma processing chamber;
a first power source configured to supply a first electric signal to the antenna, the first electric signal including a first RF signal having a first RF frequency;
a second power source configured to supply a second electric signal to the at least one electrode, the second electric signal including a second RF signal having a second RF frequency;
a third power source configured to supply a third electric signal to the at least one electrode, the third electric signal including a third RF signal or a DC signal having a third RF frequency that is lower than the first RF frequency and the second RF frequency; and
a controller that includes a processor that is configured by execution of computer readable instructions stored in a computer-readable storage to control the first power source, the second power source, and the third power source so as to selectively execute an inductively coupled plasma processing mode and a capacitively coupled plasma processing mode,
wherein in the inductively coupled plasma processing mode, the first electric signal is supplied to the antenna, and the second electric signal and/or the third electric signal is supplied to the at least one electrode, and
in the capacitively coupled plasma processing mode, the first electric signal is not supplied to the antenna, and the second electric signal and the third electric signal are supplied to the at least one electrode.

13. The plasma processing apparatus according to claim 12,
wherein the third electric signal includes the third RF signal, and
the first RF signal, the second RF signal, and the third RF signal are pulsed.

14. The plasma processing apparatus according to claim 13,
wherein the third RF frequency is in a range of 100 kHz to 13.56 MHz.

15. The plasma processing apparatus according to claim 12,
wherein the third electric signal includes the third RF signal,
the first RF signal is a continuous wave, and
the second RF signal and the third RF signal are pulsed.

16. The plasma processing apparatus according to claim 12,
wherein the third electric signal includes the DC signal, and
the DC signal includes a sequence of pulses having a first voltage level during a first state of a repetition period.

17. The plasma processing apparatus according to claim 16,
wherein the first voltage level has a negative polarity.

18. The plasma processing apparatus according to claim 17,
wherein the sequence of pulses has a pulse frequency in a range of 100 kHz to 1 MHz.

19. The plasma processing apparatus according to claim 18,
wherein the DC signal has a second voltage level during a second state of the repetition period, and an absolute value of the second voltage level is smaller than an absolute value of the first voltage level.

20. The plasma processing apparatus according to claim 12,
wherein the at least one electrode includes a first electrode, and
the second electric signal and the third electric signal are supplied to the first electrode.
